(19) United States
(12) Patent Application Publication
(10) Pub. No.: US 2026/0161842 A1
(43) Pub. Date: Jun. 11, 2026

(54) METHOD FOR AUTOMATICALLY DESIGNING AIR CONDITIONING EQUIPMENT PIPING BASED ON ARTIFICIAL INTELLIGENCE MODEL AND DEVICE THEREFOR

(71) Applicant: ZYX TECHNOLOGY CO., LTD, Seoul (KR)

(72) Inventor: Jong Bok CHOI, Seoul (KR)

(73) Assignee: ZYX TECHNOLOGY CO., LTD, Seoul (KR)

(21) Appl. No.: 19/412,115

(22) Filed: Dec. 8, 2025

(30) Foreign Application Priority Data
Dec. 9, 2024 (KR) 10-2024-0181926
May 13, 2025 (KR) 10-2025-0062034

(51) Int. Cl. G06F 30/18; G06F 30/27

(52) U.S. Cl. CPC G06F 30/18; G06F 30/27

(57) ABSTRACT

According to various exemplary embodiments, an air conditioning equipment piping automatic design device based on an artificial intelligence model inputs an architecture drawing on which the air conditioning equipment is not displayed to the artificial intelligence model, generates air conditioning equipment installation information including an installation location of the air conditioning equipment or a piping route from the architecture drawing on which the air conditioning equipment is not displayed using the artificial intelligence model, and automatically generates an air conditioning equipment installation design drawing including the air conditioning equipment installation information.

### BACKGROUND

### Technical Field

The present disclosure relates to a method for automatically designing air conditioning equipment piping based on an artificial intelligence model and an apparatus thereof.

### Description of the Related Art

The contents described in this section merely provide background information on the present exemplary embodiment but do not constitute the related art.

A floor heating piping system of a building is an important component which provides a comfortable thermal environment to a dweller and is configured by an insulation layer which reduces heat loss and a piping layer for efficient heat transfer.

Although a design standard has been established for resistance of heat transmission or a strength of an insulator of the insulation layer, a clear design standard for the piping layer has not been established.

This is because there are various zoning methods, pipe spacing, and pipe lengths to satisfy a required thermal characteristic depending on the purpose of the building (for example, apartments, daycare centers, and elderly care facilities) and characteristics of the occupants (for example, adults, children, and the elderly).

For example, the elderly spends more time indoors due to the weaker immune system and the limited mobility as compared with the normal adult so that even in the elderly facility with the similar floor layout, more heating pipes need to be designed with a narrower pipe spacing, unlike the apartment.

Due to these features, generally, the floor heating piping design is manually carried out based on the designer's knowledge and experience.

However, the manual design method of the related art has the following limitations. First, lots of time and cost are required for the manual design process. Second, various design plans considering different requirements need to be deduced depending on the purpose of the buildings and the characteristics of the occupants, which requires professional knowledge and experiment of the designer. Third, even under the same condition, the design plans may vary depending on the designer's knowledge and experience.

### RELATED ART DOCUMENT

### Patent Document

(Patent Document 1) Korean Registered Patent Publication No. 10-2795929 (Apr. 10, 2025)

### SUMMARY

An object to be achieved by the present disclosure is to provide a method for automatically designing an air conditioning equipment piping based on an artificial intelligence model which automatically analyzes an architectural drawing and designs an air conditioning equipment piping design using an artificial intelligence model to reduce a design time and cost and provides an optimized design suitable for the space characteristic, thereby improving a construction quality and energy efficiency and a device therefor.

Other and further objects of the present disclosure which are not specifically described can be further considered within the scope easily deduced from the following detailed description and the effect.

In order to achieve the above-described objects, according to an aspect of the present disclosure, an air conditioning equipment piping automatic design device based on an artificial intelligence model includes a memory which stores one or more programs to automatically design an air conditioning equipment piping based on an artificial intelligence model; and one or more processors which perform operations according to one or more programs, and the processor is configured to input an architecture drawing on which the air conditioning equipment is not displayed to the artificial intelligence model, generate air conditioning equipment installation information including an installation location of the air conditioning equipment or a piping route from the architecture drawing on which the air conditioning equipment is not displayed using the artificial intelligence model, and automatically generate an air conditioning equipment installation design drawing including the air conditioning equipment installation information.

The processor is configured to classify a purpose of a space from an architecture drawing in which the air conditioning equipment is not displayed, calculate an area of each classified space, calculate a cooling/heating load for each space, calculate a capacity of the air conditioning equipment based on the calculated cooling/heating load, and generate the air conditioning equipment installation information including a capacity, using the artificial intelligence model.

The processor is configured to classify a purpose of the space from the architecture drawing in which the air conditioning equipment is not displayed to identify a location of an utility room and generate the air conditioning equipment installation information to locate the outdoor unit in the identified location of the utility room, using the artificial intelligence model.

The piping of the air conditioning equipment includes a refrigerant pipe, a drain pipe, and a branch pipe, and a piping route of the drain pipe is determined according to information provided from the outside, and the processor generates the air conditioning equipment installation information including the piping route of the refrigerant pipe or the branch pipe, using the artificial intelligence model.

The processor is configured to classify the interior wall and the exterior wall from the architecture drawing on which the air conditioning equipment is not displayed, determines the piping route of the air conditioning equipment so as to detour the exterior wall and pass through or detour the interior wall, along the classified interior wall and exterior wall, and generate air conditioning equipment installation information to which the piping route is reflected, using the artificial intelligence model.

The air conditioning equipment includes an indoor unit and an outdoor unit of an air conditioner, The piping of the air conditioning equipment includes a refrigerant pipe, a drain pipe, and a branch pipe, and The processor is configured to individually generate air conditioning equipment installation information for each of the indoor unit, the outdoor unit, the refrigerant pipe, the drain pipe, and the branch pipe, using the artificial intelligence model and individually generate the air conditioning equipment installation design drawing which reflects air conditioning equipment installation information for each of the indoor unit, the outdoor unit, the refrigerant pipe, the drain pipe, and the branch pipe which is individually generated.

The artificial intelligence model is a vision transformer (ViT) based model

In order to achieve the above-described objects, according to an aspect of the present disclosure, a method performed by a device including a memory which stores one or more programs to automatically design an air conditioning equipment piping based on an artificial intelligence model; and one or more processors which perform operations according to one or more programs, includes inputting an architecture drawing on which an air conditioning equipment is not displayed to the artificial intelligence model; generating air conditioning equipment installation information including an installation location of the air conditioning equipment or a piping route from the architecture drawing on which the air conditioning equipment is not displayed using the artificial intelligence model; and automatically generating an air conditioning equipment installation design drawing including the air conditioning equipment installation information.

In the generating of air conditioning equipment installation information, the artificial intelligence model is used to classify a purpose of a space from an architecture drawing in which the air conditioning equipment is not displayed, calculate an area of each classified space, calculate a cooling/heating load for each space, calculate a capacity of the air conditioning equipment based on the calculated cooling/heating load, and generate the air conditioning equipment installation information including a capacity.

In the generating of air conditioning equipment installation information, the artificial intelligence model is used to classify a purpose of the space from the architecture drawing in which the air conditioning equipment is not displayed to identify a location of an utility room and generate the air conditioning equipment installation information to locate the outdoor unit in the identified location of the utility room.

The piping of the air conditioning equipment includes a refrigerant pipe, a drain pipe, and a branch pipe, and a piping route of the drain pipe is determined according to information provided from the outside, and in the generating of air conditioning equipment installation information, the artificial intelligence model is used to generate the air conditioning equipment installation information including the piping route of the refrigerant pipe or the branch pipe.

In the generating of air conditioning equipment installation information, The artificial intelligence model is used to classify the interior wall and the exterior wall from the architecture drawing on which the air conditioning equipment is not displayed, determines the piping route of the air conditioning equipment so as to detour the exterior wall and pass through or detour the interior wall, along the classified interior wall and exterior wall, and generate air conditioning equipment installation information to which the piping route is reflected.

The air conditioning equipment includes an indoor unit and an outdoor unit of an air conditioner, The piping of the air conditioning equipment includes a refrigerant pipe, a drain pipe, and a branch pipe, and in the generating of air conditioning equipment installation information, the artificial intelligence model is used to individually generate air conditioning equipment installation information for each of the indoor unit, the outdoor unit, the refrigerant pipe, the drain pipe, and the branch pipe, and in the automatically generating of air conditioning equipment installation design drawing, the air conditioning equipment installation design drawing which reflects air conditioning equipment installation information for each of the indoor unit, the outdoor unit, the refrigerant pipe, the drain pipe, and the branch pipe which is individually generated is individually generated.

In order to achieve the above-described objects, according to an aspect of the present disclosure, a computer program is stored in a computer readable recording medium to allow a computer to execute any one of the above-described artificial intelligence model based air conditioning equipment piping automatic design methods.

As described above, according to an exemplary embodiment of the present disclosure, a method for automatically designing an air conditioning equipment piping based on an artificial intelligence model and a device therefor are applied to automatically analyze an architectural drawing and design an air conditioning equipment piping design using an artificial intelligence model, thereby reducing a design time and cost and providing an optimized design suitable for the space characteristic to improve a construction quality and energy efficiency and a device therefor.

Even if the effects are not explicitly mentioned here, the effects described in the following specification which are expected by the technical features of the present disclosure and their potential effects are handled as described in the specification of the present disclosure.

### BRIEF DESCRIPTION OF THE DRAWINGS

FIG. 1 is a flowchart for explaining a method for automatically designing an air conditioning equipment piping based on an artificial intelligence model according to an exemplary embodiment of the present disclosure;

FIG. 2 is a view for explaining a configuration of a device for automatically designing an air conditioning equipment piping based on an artificial intelligence model according to an exemplary embodiment of the present disclosure;

FIGS. 3 to 9 are views regarding placement of indoor and outdoor units of an air conditioner, a route design of a refrigerant pipe and a drain pipe, a room area, and a load calculation performed in a device for automatically designing an air conditioning equipment piping based on an artificial intelligence model according to an exemplary embodiment of the present disclosure; and

FIGS. 10 to 39 are views for explaining a view included in a dataset for training an artificial intelligence model used by a device for automatically designing an air conditioning equipment piping based on an artificial intelligence model according to an exemplary embodiment of the present disclosure.

### DETAILED DESCRIPTION OF THE EMBODIMENT

Hereinafter, embodiments of the present disclosure will be described in detail with reference to the accompanying drawings. Advantages and characteristics of the present disclosure and a method of achieving the advantages and characteristics will be clear by referring to preferable embodiments described below in detail together with the accompanying drawings. However, the present disclosure is not limited to exemplary embodiments disclosed herein but will be implemented in various different forms. The exemplary embodiments are provided by way of example only so that a person of ordinary skilled in the art can fully understand the disclosures of the present disclosure and the scope of the present disclosure. Therefore, the present disclosure will be defined only by the scope of the appended claims. Unless otherwise defined, all terms (including technical and scientific terms) used in the present specification may be used as the meaning which may be commonly understood by the person with ordinary skill in the art, to which the present disclosure belongs. It will be further understood that terms defined in commonly used dictionaries should not be interpreted in an idealized or excessive sense unless expressly and specifically defined.

Terms used in the present application are just used to describe a specific exemplary embodiment and do not intend to limit the present disclosure and a singular expression may include a plural expression as long as it is not apparently contextually different. In the present application, it should be understood that term “have” “may have”, “include” or “may include” indicates that a feature, a number, a step, an operation, a component, a part or a combination thereof described in the specification is present, but do not exclude a possibility of presence or addition of one or more other features, numbers, steps, operations, components, parts or combinations thereof, in advance. Terms including an ordinary number, such as first and second, are used for describing various constituent elements, but the constituent elements are not limited by the terms.

The above terms are used only to distinguish one component from the other component. For example, without departing from the scope of the present disclosure, a first component may be referred to as a second component, and similarly, a second component may be referred to as a first component. A term of and/or includes combination of a plurality of related elements or any one of the plurality of related elements.

In the present specification, in each step, numerical symbols (for example, a, b, and c) are used for the convenience of description, but do not explain the order of the steps so that unless the context apparently indicates a specific order, the order may be different from the order described in the specification. In the present specification, in each step, numerical symbols (for example, a, b, and c) are used for the convenience of description, but do not explain the order of the steps so that unless the context apparently indicates a specific order, the order may be different from the order described in the specification.

The term “˜processor” used in the specification refers to a software or hardware component such as a field programmable gate array (FPGA) or an ASIC and “˜processor” performs some functions. However, “˜processor” is not limited to the software or the hardware. “˜processor” may be configured to be in an addressable storage medium or may be configured to reproduce one or more processors. Accordingly, as an example, “˜processor” includes components such as software components, object oriented software components, class components, and task components, processes, functions, attributes, procedures, subroutines, segments of a program code, drivers, a firmware, a microcode, a circuit, data, database, and data structures. A function which is provided in the components and “˜processors” may be combined with a smaller number of components and “˜processors” or divided into additional components and “˜processors”.

Hereinafter, various exemplary embodiments of a method for automatically designing an air conditioning equipment piping based on an artificial intelligence model according to the present disclosure and a device therefor will be described in detail with reference to the accompanying drawings.

In the present disclosure, the air-conditioning equipment includes an indoor unit (wall-mounted, ceiling-mounted, cassette type, multi-port type), an outdoor unit (single type, multi type), a refrigerant pipe (including a liquid pipe, a gas pipe, and a communication line), a drain pipe, a branch pipe (T-type, Y-type, and a distributor), a duct (a main duct and a sub duct), a blower (Fan coil unit), a diffuser, a grill, a thermostat, a pressure and temperature sensor, an electronic valve (EXV), a motor valve, a heat pump, a heat exchanger, a boiler, a chiller, an air purification filter, such as a prefilter, a HEPA filter, or an activated carbon filter, a humidifier, a dehumidifier, an air cleaner, a drain pump, a wired line tray, a pipe support, a soundproofing material, an insulating material, and an integrated control system.

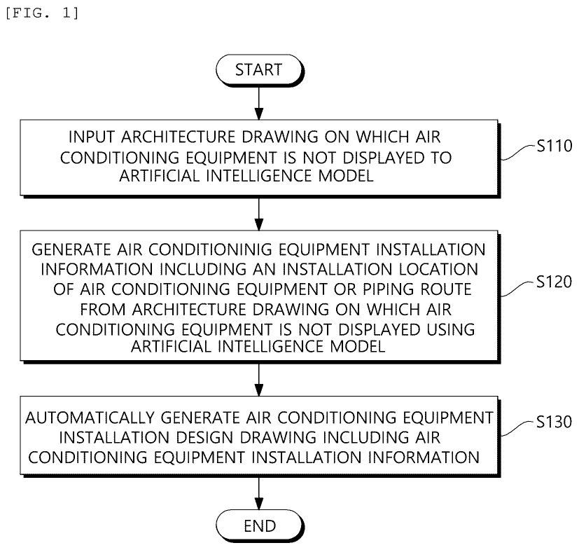

FIG. 1 is a flowchart for explaining a method for automatically designing an air conditioning equipment piping based on an artificial intelligence model according to an exemplary embodiment of the present disclosure.

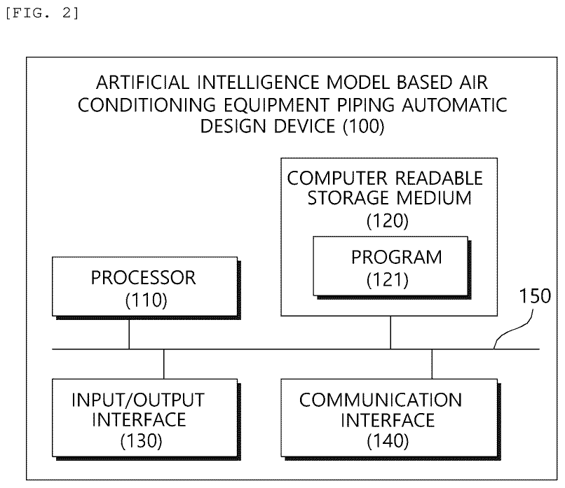

The artificial intelligence model based air conditioning equipment piping automatic design method may be performed by a device including a memory which stores one or more programs to automatically design an air conditioning equipment piping based on an artificial intelligence model and one or more processors which perform operations according to one or more programs. For example, the artificial intelligence model based air conditioning equipment piping automatic design method is performed by an artificial intelligence model based air conditioning equipment piping automatic design device illustrated in FIG. 2.

In step S110, a processor inputs an architecture drawing on which air conditioning equipment is not displayed to the artificial intelligence model.

In step S120, the processor generates air conditioning equipment installation information including an installation location of the air conditioning equipment or a piping route from the architecture drawing on which the air conditioning equipment is not displayed, using the artificial intelligence model.

The installation information of the air conditioning equipment includes an installation location of the air conditioning equipment, a cooling/heating load according to an area and a purpose of each space, a placement location of the indoor unit and the outdoor unit, an identification result of a positional reference space (for example, a utility room) of an outdoor unit, a result of calculating an indoor unit capacity, a route of a refrigerant pipe and a drain pipe, a position and a type of a branch pipe, or information indicating whether the piping route passes through or detours an interior wall or an exterior wall. Further, some information such as determination of a route of a drain pipe may be reflected according to an external input (for example, a user setting value).

In step S130, the processor automatically generates an air conditioning equipment installation design drawing including air conditioning equipment installation information.

The air conditioning equipment installation design drawing including air conditioning equipment installation information is drawing data which visualizes installation information (for example, indoor/outdoor unit placement, a piping route, and branch pipe location) generated by the artificial intelligence model and is configured by CAD (DWG, DXF), vector graphic (SVG), PDF, or BIM (IFC) file format. The air conditioning equipment installation design drawing includes information for individual components in the unit of layers and includes a piping route, a pipe diameter, equipment names, and a construction reference line.

In step S120, the processor uses the artificial intelligence model to classify a purpose of a space from an architecture drawing on which the air conditioning equipment is not displayed, calculate an area of each classified space, calculate a cooling/heating load for each space based on the area, calculate a capacity of the air conditioning equipment based on the calculated cooling/heating load, and generate the air conditioning equipment installation information including a capacity.

The processor classifies the purpose of each space from the drawing and calculates the area using the artificial intelligence model, and then calculates a load for each space by applying a predetermined load coefficient per area (W/m² or kW/m²). For example, if an area of bedroom 1 is 16.39 m² and a load coefficient is 0.1 kW/m², the load of the corresponding space may be calculated by 16.39×0.1 (=1.6 kW). The processor automatically selects an indoor unit having an appropriate capacity from an indoor unit lineup (for example, 1.2 kW, 1.6 kW, and 2.3 kW) and adds all the loads per room to calculate a total capacity of the outdoor unit.

A vision transformer (ViT) based artificial intelligence model is trained based on learning data in which a space label, a boundary, an object (windows and doors), and area information are annotated on various drawing forms) to classify the purpose of the space and calculate the area from the architecture drawing image. When a new architecture drawing is input, the artificial intelligence model automatically classifies the space and calculates the area, and then applies a cooling/heating load reference per area to calculate a load per space and calculate an appropriate capacity of the air conditioning equipment according to the result.

In step S120, the processor uses the artificial intelligence model to classify a purpose of the space from the architecture drawing on which the air conditioning equipment is not displayed to identify a location of an utility room and generate the air conditioning equipment installation information to place the outdoor unit in the identified location of the utility room.

A vision transformer (ViT) based artificial intelligence model is trained through learning data in which a space type (for example, living room, bedroom, kitchen, or utility room), objects (washer, window, and door), and boundary information are annotated on various floor plan images to classify the purpose of the space from the architecture drawing image and identify the utility room. When a new drawing is input, the artificial intelligence model classifies the space and identifies the location of the utility room therefrom, and then automatically generates the air conditioning equipment installation information by designating the corresponding location as an available space for installing the outdoor unit.

The pipe of the air conditioning equipment includes a refrigerant pipe, a drain pipe, and a branch pipe.

The piping route of the drain pipe is determined according to information provided from the outside.

In step S120, the processor uses the artificial intelligence model to generate air conditioning equipment installation information including the piping route of the refrigerant pipe and the branch pipe.

The vision transformer (ViT) based artificial intelligence model is trained based on data in which a drawing image including an element, such as indoor/outdoor unit location, a wall structure, a space boundary, or a ceiling structure and a corresponding piping route are annotated to predict the piping route of the refrigerant pipe or the branch pipe from the architecture drawing image. The artificial intelligence model figures out a relationship between a spatial constrain (for example, interior walls, exterior walls, columns, and windows) and the component through a self-attention mechanism and learns a route pattern in an actual piping design. When a new architecture drawing is input, the artificial intelligence model automatically generates an optimal piping route between a start point and an end point of the refrigerant pipe or the branch pipe by considering the connection between the indoor unit and the outdoor unit.

In step S120, the processor uses the artificial intelligence model to classify the interior wall and the exterior wall from the architecture drawing on which the air conditioning equipment is not displayed, determine the piping route of the air conditioning equipment so as to detour the exterior wall and pass through or detour the interior wall, along the classified interior wall and exterior wall, and generate air conditioning equipment installation information to which the piping route is reflected.

In order to classify the interior wall and the exterior wall from the architecture drawing and determine the piping route based thereon, the vision transformer based artificial intelligence model is trained by learning data in which a piping route design example is annotated on various floor plan images together with interior wall/exterior wall classification information. The artificial intelligence model learns a wall thickness, a material symbol, and a placement characteristic of an object adjacent to the wall through the self-attention mechanism and learns a structure recognition ability which reflects construction constrains that the interior wall is penetrated and the exterior wall is avoided. When a new architecture drawing is input, the artificial intelligence model automatically classifies the wall into an interior wall and an exterior wall and determines a route allowing the refrigerator pipe or the drain pipe to detour the exterior wall and pass through or detour the interior wall according to the result.

The air conditioning equipment includes an indoor unit and an outdoor unit of an air conditioner.

The pipe of the air conditioning equipment includes a refrigerant pipe, a drain pipe, and a branch pipe.

In step S120, the processor uses the artificial intelligence model to individually generate air conditioning equipment installation information for each of the indoor unit, the outdoor unit, the refrigerant pipe, the drain pipe, and the branch pipe.

In step S130, the processor individually generates the air conditioning equipment installation design drawings which reflect air conditioning equipment installation information for each of the indoor unit, the outdoor unit, the refrigerant pipe, the drain pipe, and the branch pipe which is individually generated.

A coffered ceiling is various shapes of ceiling retreated regions formed on a living room ceiling. The coffered ceiling is a downwardly recessed rectangular structure formed on the living room ceiling. The coffered ceiling is a structure dented into the living room ceiling and is considered as a region where the pipe cannot pass through. Accordingly, during the learning, the artificial intelligence model is trained to recognize the architecture drawing on which the coffered ceiling is displayed (for example, a rectangular symbol in the center of the living room) and classifies the corresponding region as a no pipe-passing region similar to the wall. The artificial intelligence model is trained to identify the location of the coffered ceiling based on the spatial symbol and the structural context in the drawing and set the location of the coffered ceiling as an avoidance zone during computation of the piping route. Specifically, the vision transformer model identifies the location and the shape of the coffered ceiling in the drawing from the relationship with other spatial elements by means of the self-attention structure. If there is a coffered ceiling, the processor sets a detour route so as not to allow the route of the refrigerant pipe or the branch pipe to pass through the corresponding region, based on the result deduced by the artificial intelligence model. In contrast, if the coffered ceiling is not displayed, it is possible to design to pass through the living room center along a straight route.

In FIG. 2, the respective processes are sequentially performed, but this is merely illustrative and those skilled in the art may apply various modifications and changes by changing the order illustrated in FIG. 2 or performing one or more processes in parallel or adding another process without departing from the essential gist of the exemplary embodiment of the present disclosure.

FIG. 2 is a view for explaining a configuration of a device for automatically designing an air conditioning equipment piping based on an artificial intelligence model according to an exemplary embodiment of the present disclosure.

The air conditioning equipment piping equipment automatic design device 100 based on an artificial intelligence model includes at least one processor 110, a computer readable storage medium 120, and a communication bus 150.

The processor 110 controls to operate as the air conditioning equipment piping automatic design device 100 based on an artificial intelligence model. For example, the processor 110 may execute one or more programs 120 stored in the computer readable storage medium 121. One or more programs 121 may include one or more computer executable instructions and the computer executable instruction may be configured to allow the air conditioning equipment piping automatic design device 100 based on an artificial intelligence model to perform the operations according to the exemplary embodiments when it is executed by the processor 110.

The computer readable storage medium 120 is configured to store a computer executable instruction or program code, program data and/or other appropriate format of information. A computer executable instruction or program code, program data and/or other appropriate type of information may also be provided by an input/output interface 130 or a communication interface 140. The program 120 stored in the computer readable storage medium 121 includes a set of instructions executable by the processor 110. In one exemplary embodiment, the computer readable storage medium 120 may be a memory (a volatile memory such as a random access memory, a non-volatile memory, or an appropriate combination thereof), one or more magnetic disk storage devices, optical disk storage devices, flash memory devices, and another format of storage media which are accessed by the air conditioning equipment piping automatic design device 100 based on an artificial intelligence mode 100 and store desired information, or an appropriate combination thereof.

The communication bus 150 interconnects various other components of the air conditioning equipment piping automatic design device 100 based on an artificial intelligence model including the processor 110 and the computer readable storage medium 120 to each other.

The air conditioning equipment piping automatic design device 100 based on an artificial intelligence model may include one or more input/output interfaces 130 and one or more communication interfaces 140 which provide an interface for one or more input/output devices. The input/output interface 130 and the communication interface 140 are connected to the communication bus 150. The input/output device (not illustrated) may be connected to the other components of the air conditioning equipment piping automatic design device 100 based on an artificial intelligence mode 100 by means of the input/output interface 130.

The processor 110 inputs an architecture drawing on which the air conditioning equipment is not displayed to the artificial intelligence model, generates the air conditioning equipment installation information including an installation location of the air conditioning equipment or a piping route from the architecture drawing on which the air conditioning equipment is not displayed using the artificial intelligence model, and automatically generates an air conditioning equipment installation design drawing including the air conditioning equipment installation information.

The processor 110 uses the artificial intelligence model to classify a purpose of a space from an architecture drawing on which the air conditioning equipment is not displayed, calculate an area of each classified space, calculate a cooling/heating load for each space, calculate a capacity of the air conditioning equipment based on the calculated cooling/heating load, and generate the air conditioning equipment installation information including a capacity.

The processor 110 uses the artificial intelligence model to classify a purpose of the space from the architecture drawing on which the air conditioning equipment is not displayed to identify a location of an utility room and generate the air conditioning equipment installation information to place the outdoor unit in the identified location of the utility room.

The pipe of the air conditioning equipment includes a refrigerant pipe, a drain pipe, and a branch pipe.

The piping route of the drain pipe is determined according to information provided from the outside.

The processor 110 uses the artificial intelligence model to generate air conditioning equipment installation information including the piping route of the refrigerant pipe and the branch pipe.

The processor 110 uses the artificial intelligence model to classify the interior wall and the exterior wall from the architecture drawing on which the air conditioning equipment is not displayed, determine the piping route of the air conditioning equipment so as to detour the exterior wall and pass through or detour the interior wall, along the classified interior wall and exterior wall, and generate air conditioning equipment installation information to which the piping route is reflected.

The air conditioning equipment includes an indoor unit and an outdoor unit of an air conditioner.

The pipe of the air conditioning equipment includes a refrigerant pipe, a drain pipe, and a branch pipe.

The processor 110 uses the artificial intelligence model to individually generate air conditioning equipment installation information for each of the indoor unit, the outdoor unit, the refrigerant pipe, the drain pipe, and the branch pipe and individually generate the air conditioning equipment installation design drawings which reflects air conditioning equipment installation information for each of the indoor unit, the outdoor unit, the refrigerant pipe, the drain pipe, and the branch pipe which is individually generated.

The artificial intelligence model may be a vision transformer (ViT) based model. The artificial intelligence model is built by a step of building a dataset using data including the air conditioning equipment and data which does not include air conditioning equipment and a step of learning a dataset to train an artificial intelligence model so as to predict the air conditioning equipment installation information.

Some components among various components which are exemplarily illustrated in FIG. 2 may be omitted or other component may be additionally included.

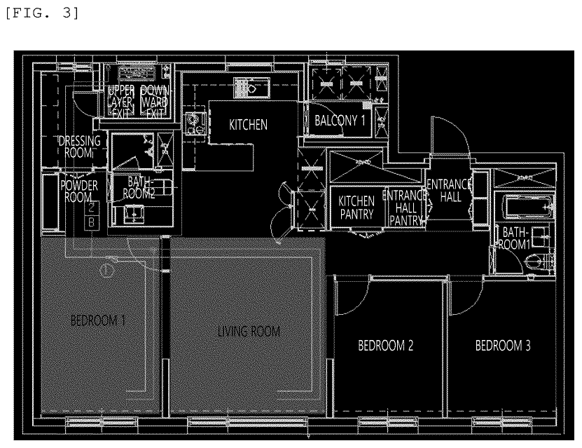

FIGS. 3 to 9 are views regarding placement of indoor and outdoor units of an air conditioner, a route design of a refrigerant pipe and a drain pipe, a room area, and a load calculation performed in a device for automatically designing an air conditioning equipment piping based on an artificial intelligence model according to an exemplary embodiment of the present disclosure.

Referring to FIG. 3, the artificial intelligence model automatically recognizes each room (for example, a living room and a bedroom) in a housing unit and calculates an area to calculate a capacity of the indoor unit by calculating a load based on a room area. Further, the artificial intelligence model detects a location of a window in the living room and places the indoor unit within a predetermined distance from a corresponding window. Together with this, the artificial intelligence model automatically designs the route of the refrigerant pipe (blue) and the drain pipe (green) and differentiates the routes from the indoor unit to the branch pipe and the pipe connection point to reflect the route to the drawing.

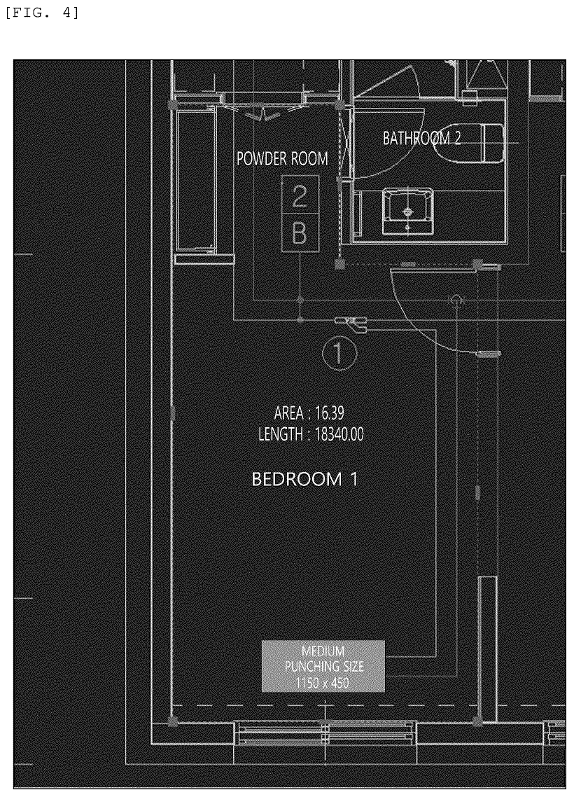

Referring to FIG. 4, the artificial intelligence model sets a direction of the refrigerant pipe and the drain pipe based on the installation location of the indoor unit and the placement of a T-shaped refrigerant connection pipe. Further, the artificial intelligence model reflects the structural condition of the coffered ceiling to design the piping route so as to allow the pipe to avoid an obstacle element or ensure a straight route.

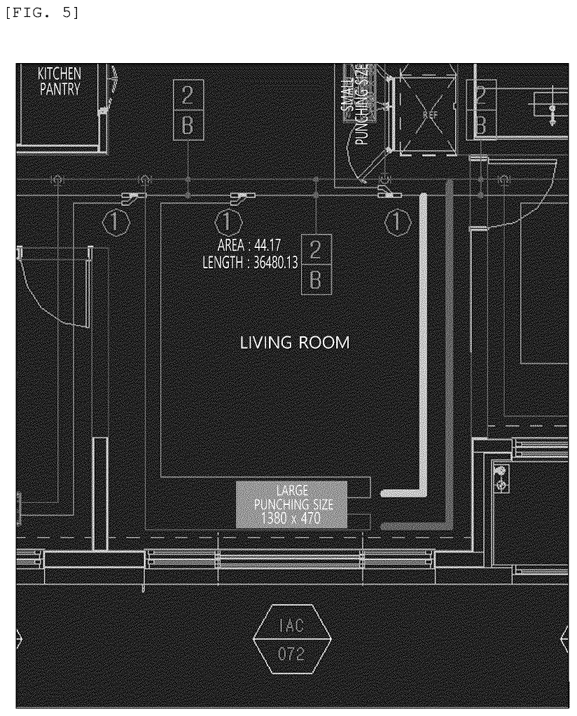

Referring to FIG. 5, the artificial intelligence model optimizes the route of the refrigerant pipe and the drain pipe connected to the branch pipe with respect to the plurality of indoor units. Specifically, the artificial intelligence model automatically determines the piping direction so as to avoid restriction elements, such as windows, ceiling, and a structure and minimize a construction interference while placing the pipes along the exterior wall.

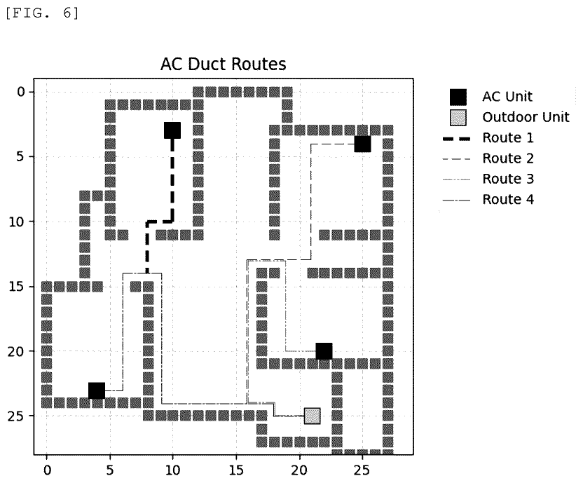

Referring to FIG. 6, after determining the locations of the indoor unit and the outdoor unit, the artificial intelligence model automatically generates a route of the plurality of refrigerant pipes and drain pipes connected from each indoor unit to the outdoor unit. The artificial intelligence model deduces route candidates Routes 1 to 4 in consideration of various construction directions and designs to visually compare interference of the pipes in each route. The artificial intelligence model may detect an overlapping section of the refrigerant pipe (blue) and the drain pipe (green).

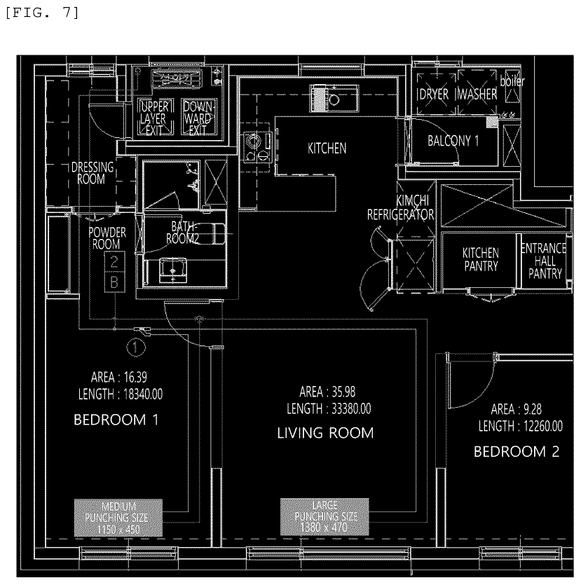

Referring to FIG. 7, the artificial intelligence model automatically places the location of the branch pipe to connect the refrigerant pipes between the plurality of indoor units and the outdoor unit. The artificial intelligence model calculates an optimal location so that the branch pipe is branched without interfering with the pipe in consideration of the installation location of each indoor unit and the piping route and also designs the separation between the pipes so as to prevent the refrigerant pipe (blue) and the drain pipe (green) from overlapping.

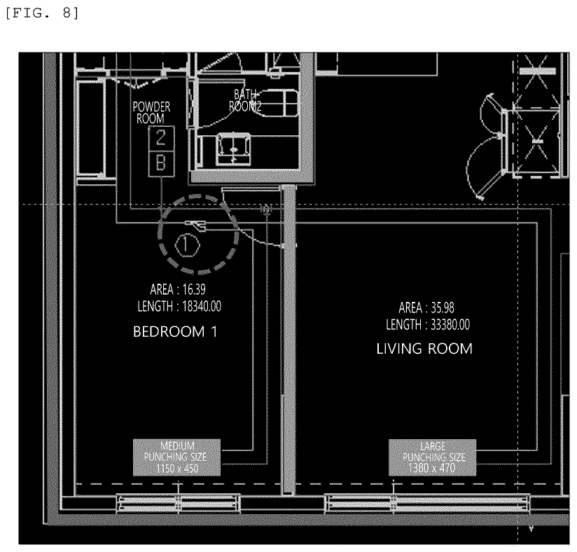

Referring to FIG. 8, the artificial intelligence model automatically divides an interior wall (wet wall) and the exterior wall during the design of the piping route and generates two design plans based on the interior wall. A first plan is a route through which the pipe bypasses along the interior wall and a second plan is a route which directly passes through the interior wall.

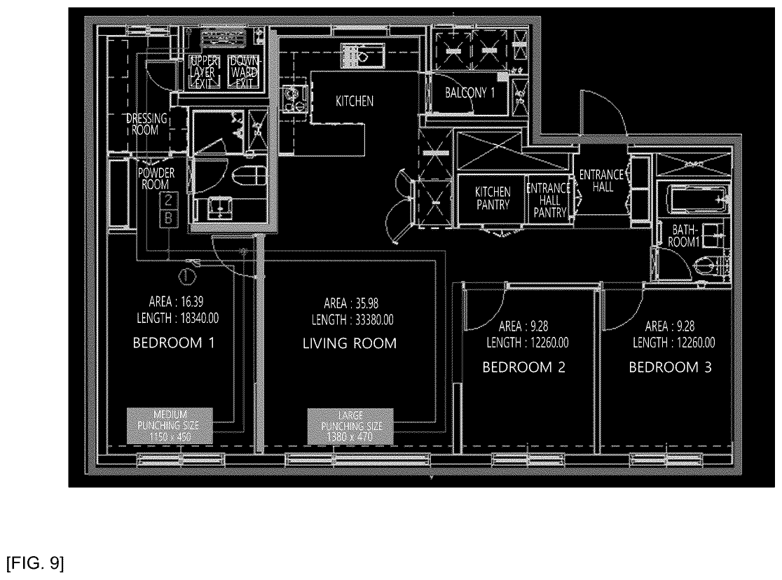

Referring to FIG. 9, the artificial intelligence model recognizes the indoor unit connection point as a fixed location and automatically designs the piping route so as to accurately connect the refrigerant pipe and the drain pipe to a corresponding point. Further, the artificial intelligence model separately designs components, such as the indoor unit, the outdoor unit, the refrigerant pipe, the drain pipe, and the branch pipe for each layer, according to a construction direction requested by the user and visualizes the components on the drawing as a construction drawing including the name of the pipe diameter and the branch pipe. The artificial intelligence model automatically quantifies and calculates a quantity of the refrigerant pipe and the drain pipe based on the drawing based design to provide information required to create an equipment list and prepare the construction.

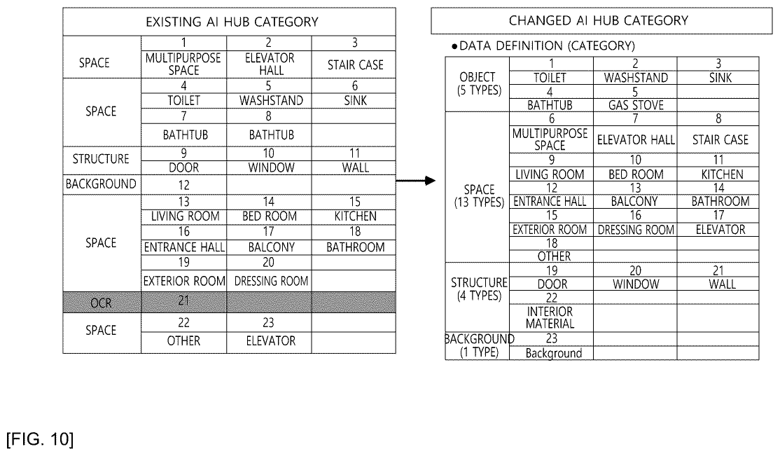

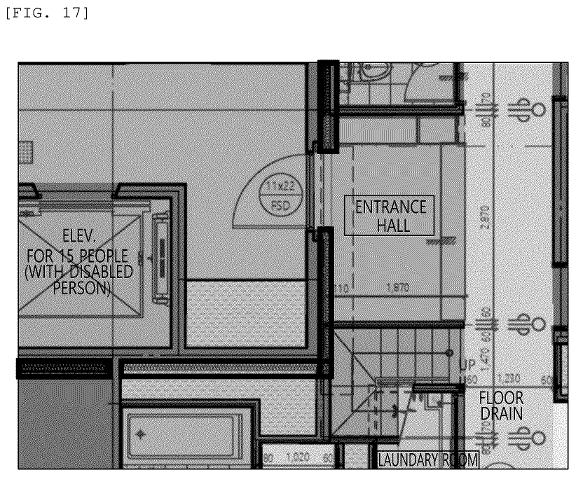

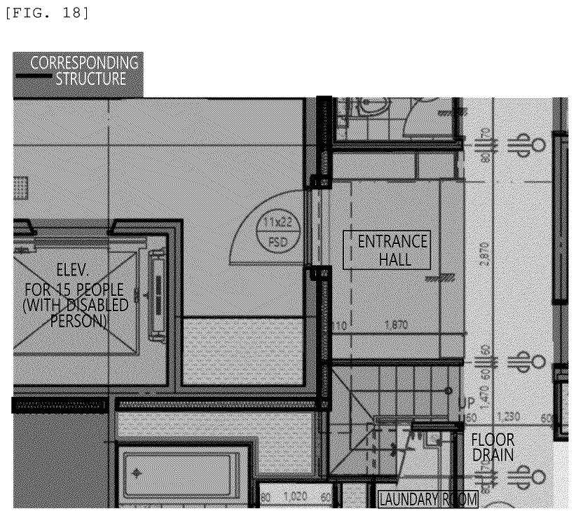

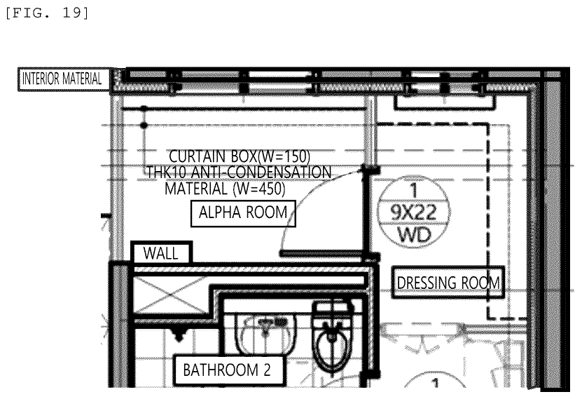

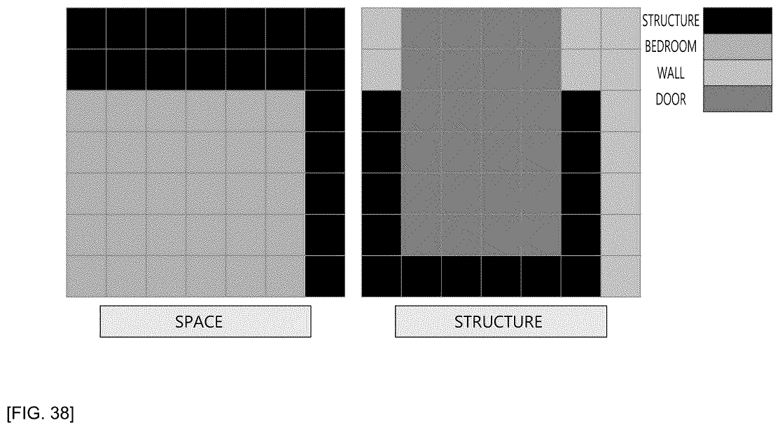

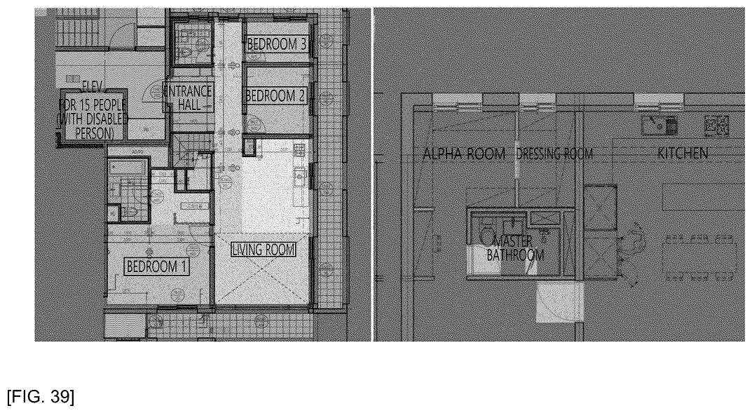

FIGS. 10 to 39 are views for explaining a view included in a dataset for training an artificial intelligence model used by a device for automatically designing an air conditioning equipment piping based on an artificial intelligence model according to an exemplary embodiment of the present disclosure.

FIG. 10 is a view included in a dataset for training an artificial intelligence model and illustrates a categorical system which classifies and labels items, such as spaces, objects, and structures.

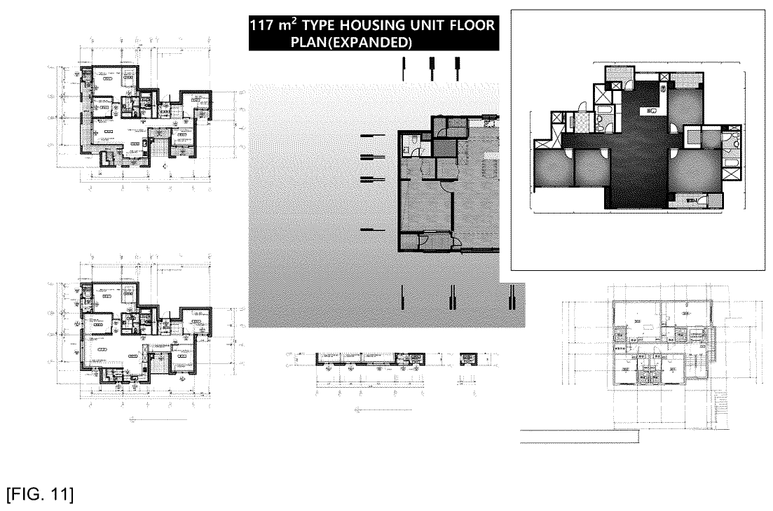

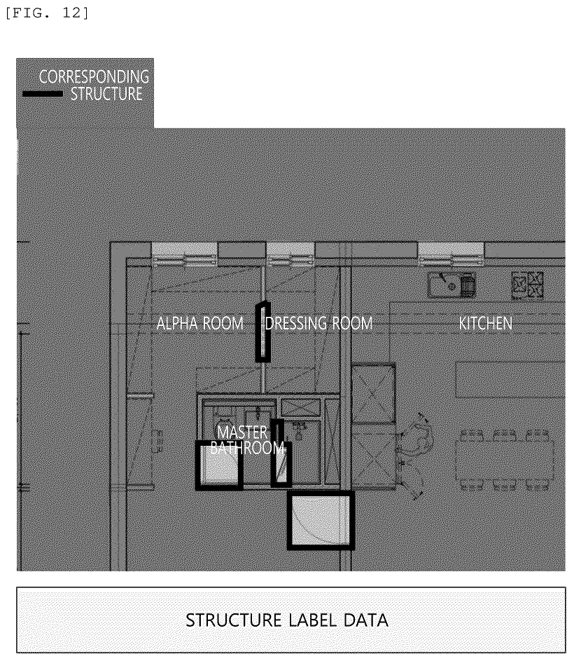

FIG. 11 is an exemplary plan view which is utilized to train an artificial intelligence model and visualizes a structure and a space placement of the housing unit. Referring to FIG. 12, highlighted parts indicate doors.

There are various types of doors installed to pass over spaces. A sliding door is designed as a rectangular shape and a hinged door is manufactured in a shape in which a quarter-circle or an octant is coupled with a rectangular.

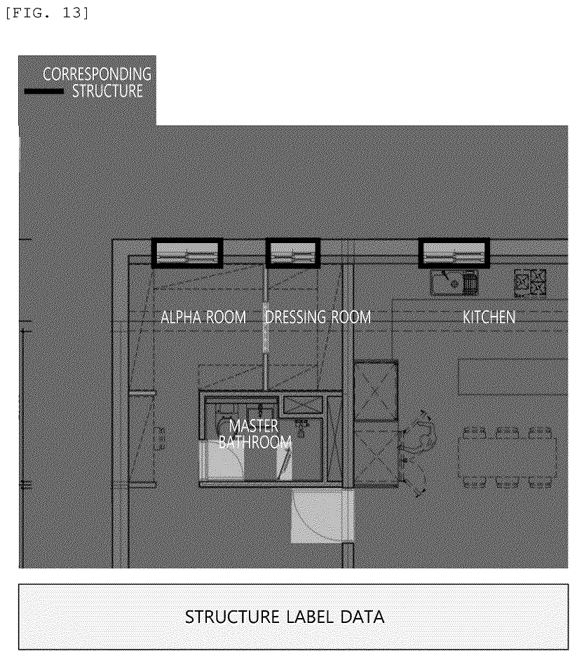

Referring to FIG. 13, highlighted parts indicate windows.

Windows are mainly located in the middle connecting the balcony and other space or a background and is configured with a rectangular shape including window linework.

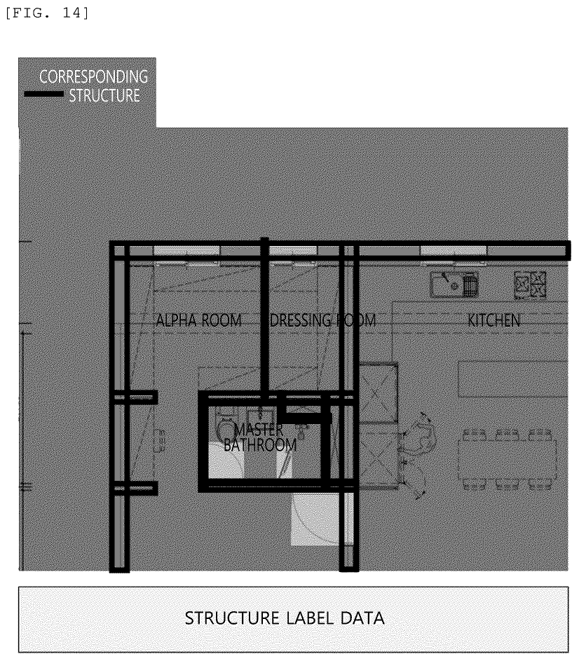

Referring to FIG. 14, highlighted parts indicate walls.

The wall is a structure which divides a space and is labeled including other structures.

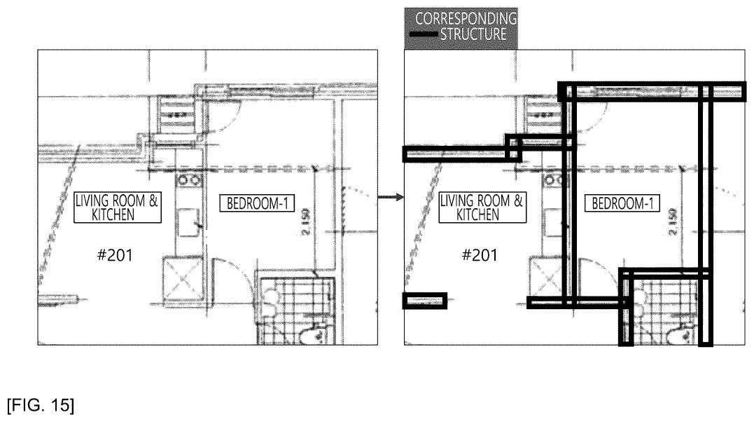

Referring to FIG. 15, if a boundary of the walls is not seen well, the labeling is performed according to the following criterion. If the boundary of the walls is not appropriately seen, it is labeled to make the thicknesses equal with respect to a center line. If the center line is not seen, the labeling is performed with respect to a location closest to the door. If there is no door, it is labeled to have the same thickness as the closest wall.

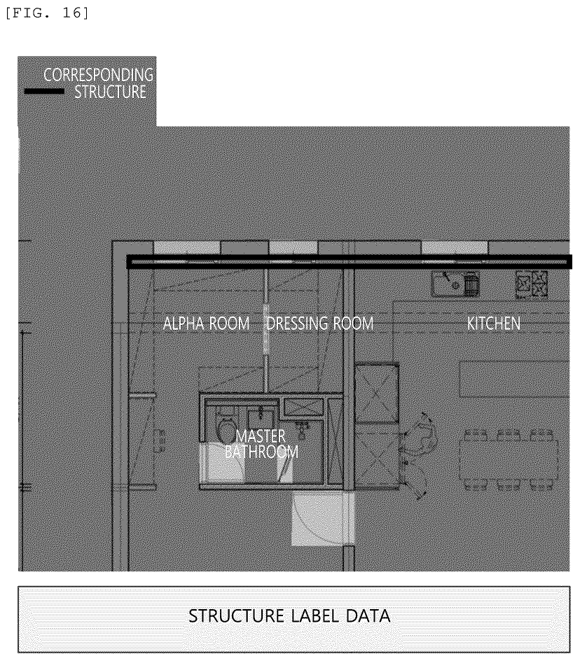

Referring to FIGS. 16 to 19, the highlighted parts represent walls and interior materials.

The interior material is closely attached to the wall and may be hollow or may include a specific linework. This structure is labeled together with another structure and is not labeled in AIHub.

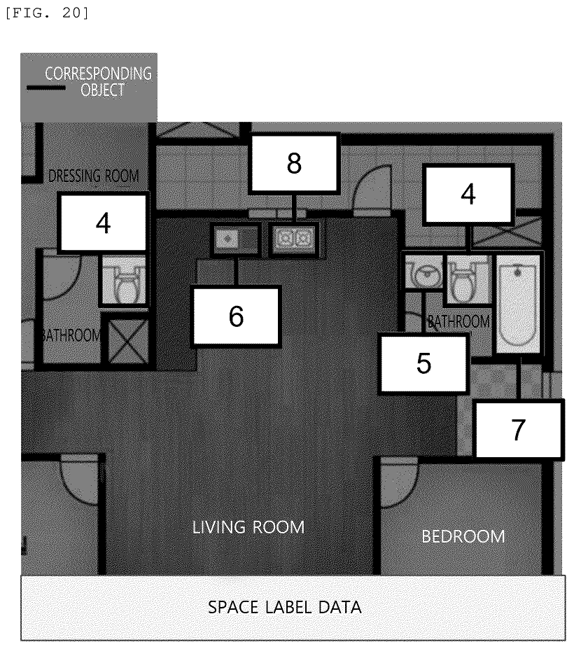

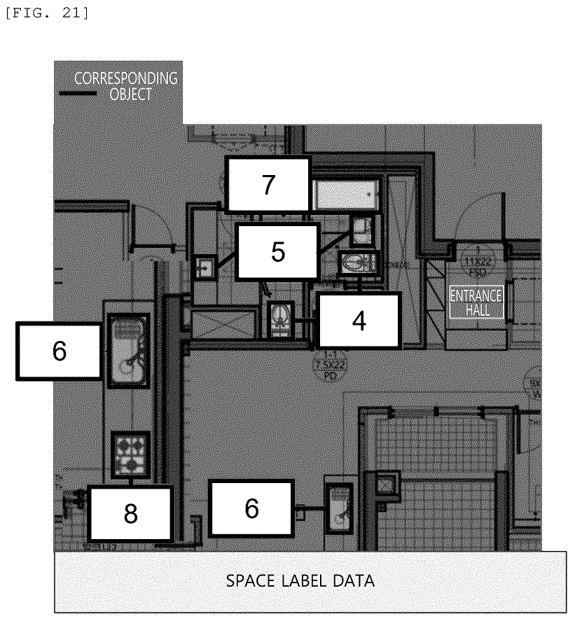

Referring to FIGS. 20 and 21, objects to be included in the drawing may include a toilet 4, a washstand 5, a sink 6, a bathtub 7, and a gas stove 8.

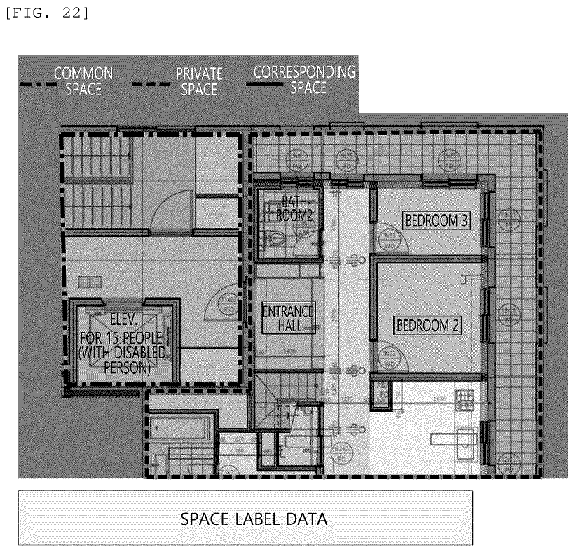

FIG. 22 is a view illustrating that the space is partitioned.

The space is defined as a set of spaces enclosed by walls or interior materials. The space is divided into three spaces. A common space refers to a space which is shared with other units and a private space refers to a space which is used exclusively by the corresponding unit. The corresponding space refers to a specific space to be described. As a common rule when the space is defined, 21_interior material should not be included.

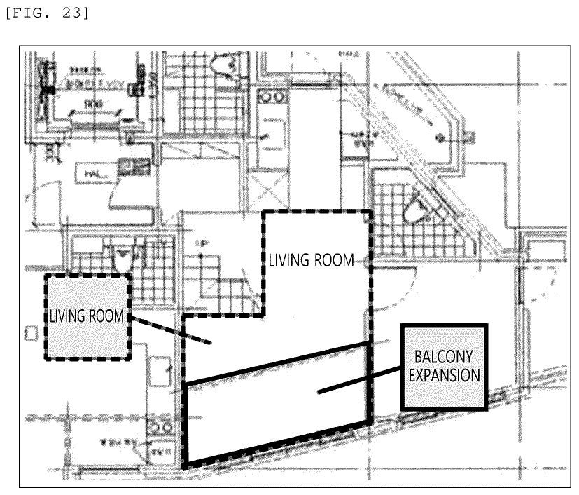

FIG. 23 is a view illustrating that a balcony is expanded.

The balcony expansion is not labeled with a separate class, but is labeled with the same class as an adjacent space.

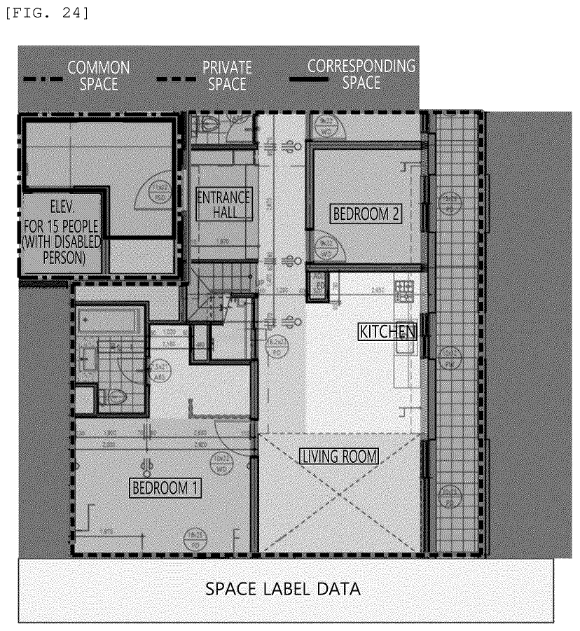

Referring to FIG. 24, a highlighted part indicates an elevator hall. The elevator hall is a common space and is adjacent to 23_elevator.

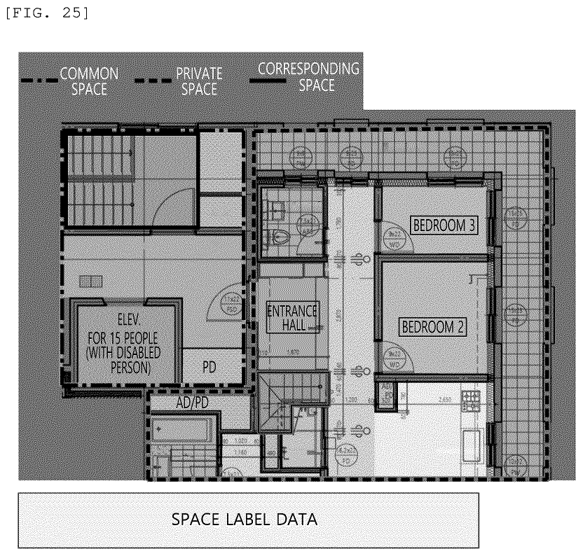

Referring to FIG. 25, a highlighted part indicates a stair case.

The stair case is classified as a common space or a private space and includes a stair linework.

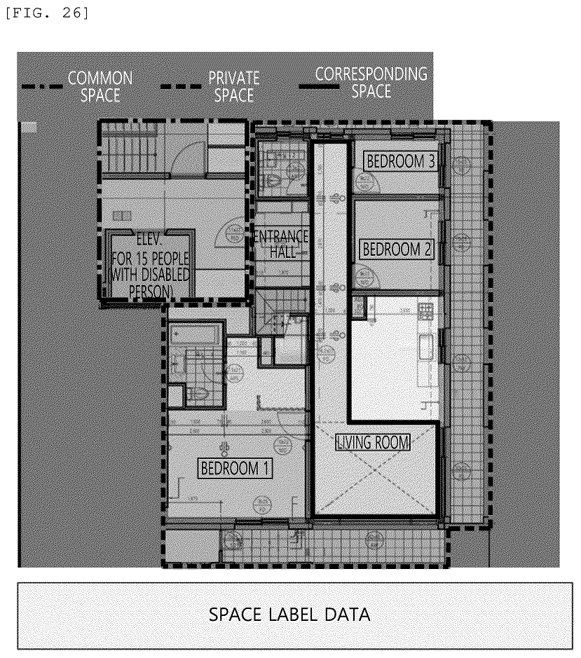

Referring to FIG. 26, a highlighted part indicates a living room.

The living room corresponds to a private space and mostly has an atypical structure. The living room is adjacent to 3_stair case, 15_kitchen, and 16_entrance and includes an area represented as a living room and a hallway. Further, when the living room is adjacent to the expanded balcony, the living room is labeled with the same class as the expanded balcony.

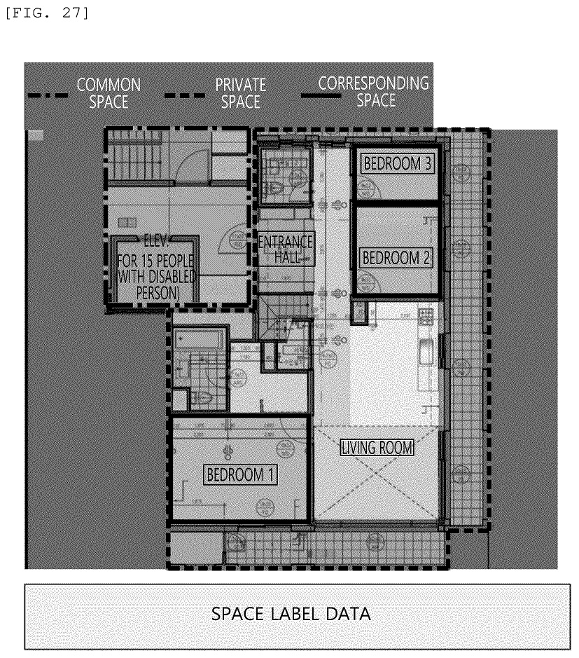

Referring to FIG. 27, highlighted parts indicate bedrooms.

The bedrooms are private spaces and are adjacent to 20_dressing room in some cases. The bedroom essentially includes one or more doors_9 and is denoted by a room, a main bedroom, or a bedroom. If the bedroom room is adjacent to the expanded balcony, the bedroom is labeled with the same class as the expanded balcony.

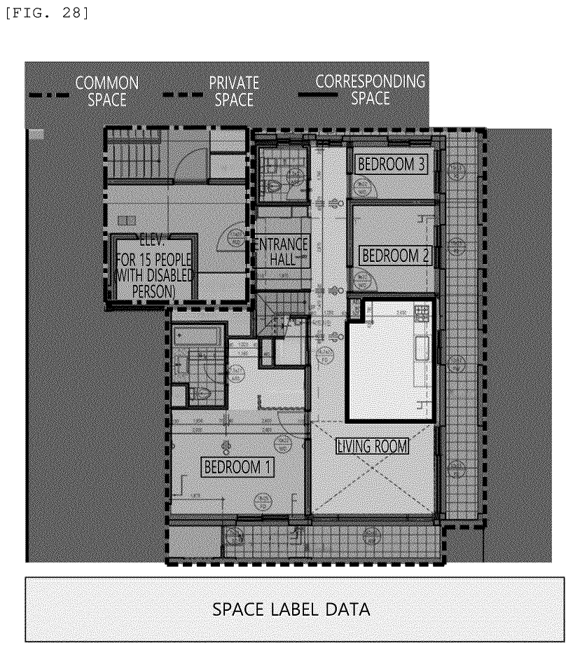

Referring to FIG. 28, a highlighted part indicates a kitchen.

The kitchen is a private space and is adjacent to 13_living room in some cases. This space includes objects, such as 6_sink and 8_gas stove and is denoted by a kitchen or a communal kitchen.

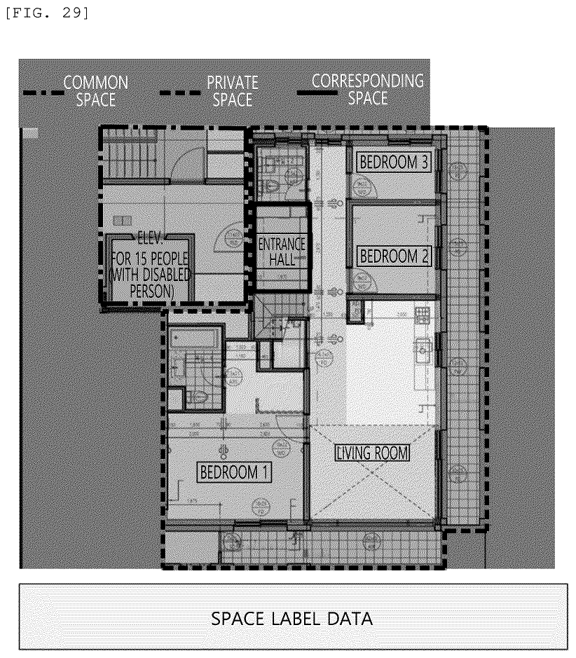

Referring to FIG. 29, a highlighted part indicates an entrance hall.

The entrance hall is a private space and is adjacent to 13_living room in some cases. In this space, built-in closet blocks are disposed in many cases and this area is filled with tile patterns.

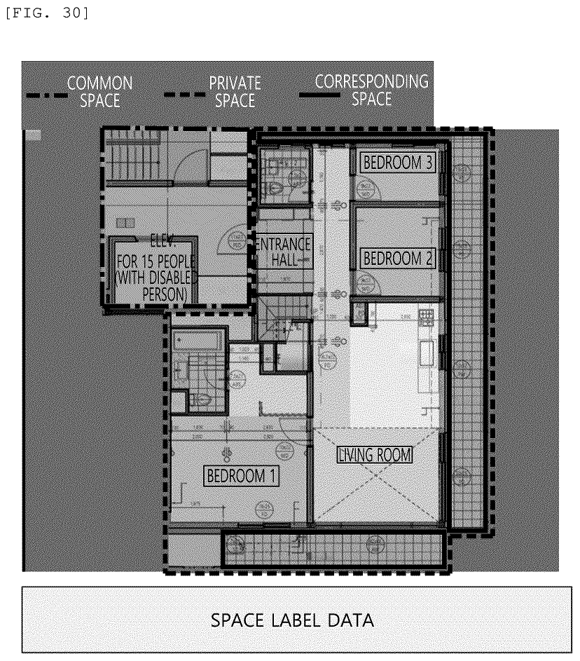

Referring to FIG. 30, a highlighted part indicates a balcony.

The balcony is a private space and is connected to 19_outdoor unit room and 9_door in some cases. Further, the balcony is connected to the other space by 10_window in many cases and is filled with tile patterns.

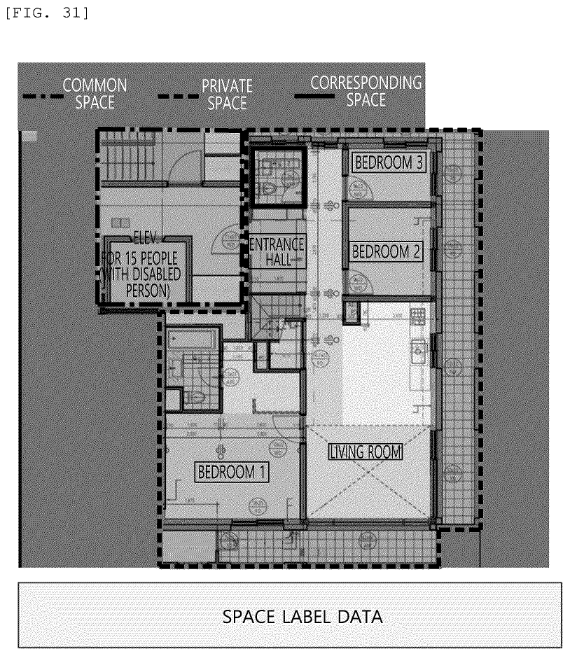

Referring to FIG. 31, a highlighted part indicates a bathroom.

The bathroom is a private space and is connected to 13_living room and 14_bedroom by 9_door. In this space, blocks, such as t4_toilet, 5_washstand, and 7_bathtub are disposed and the area is filled with tile patterns. The toilet does not have a separate name.

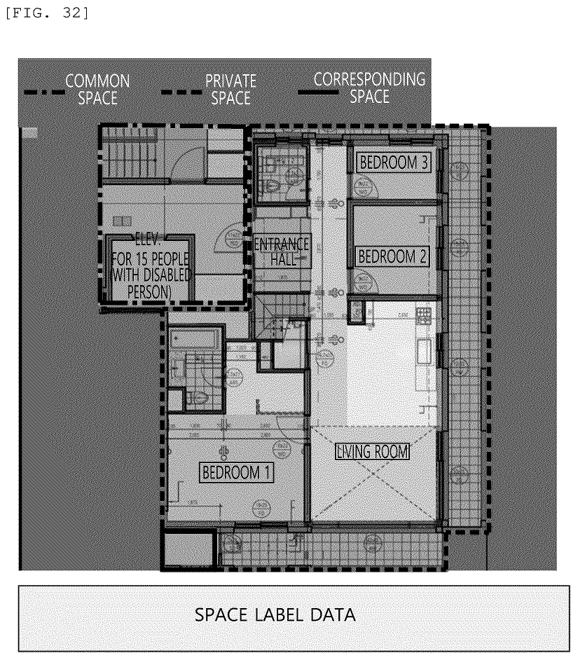

Referring to FIG. 32, a highlighted part indicates the outdoor unit room.

The outdoor unit room is a private space and is connected to 17_balcony by 9_door in many cases. In some cases, this space is filled with a tile pattern and a location of the outdoor unit is displayed.

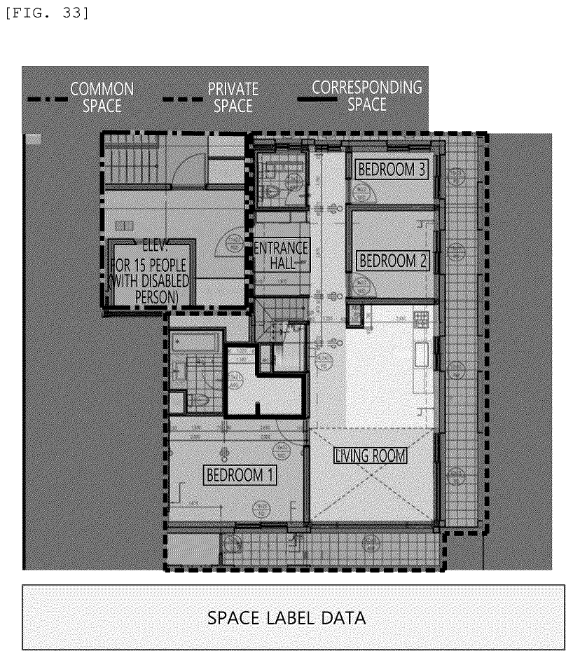

Referring to FIG. 33, a highlighted part indicates a dressing room.

The dressing room is a private room and is connected to 14_bedroom in many cases.

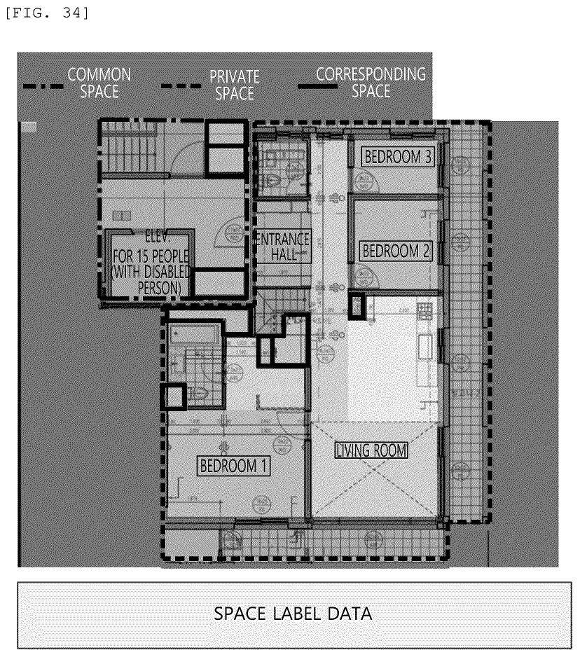

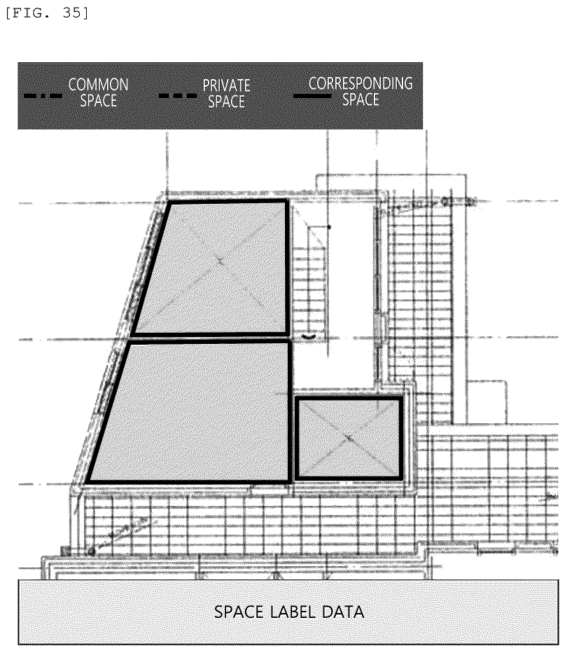

Referring to FIGS. 34 and 35, highlighted parts indicate the other spaces.

The other spaces are classified as private spaces or common spaces and may denoted by various symbols, such as X, AD/PD, or P.S. This space does not have 9_door and 10_window in many cases.

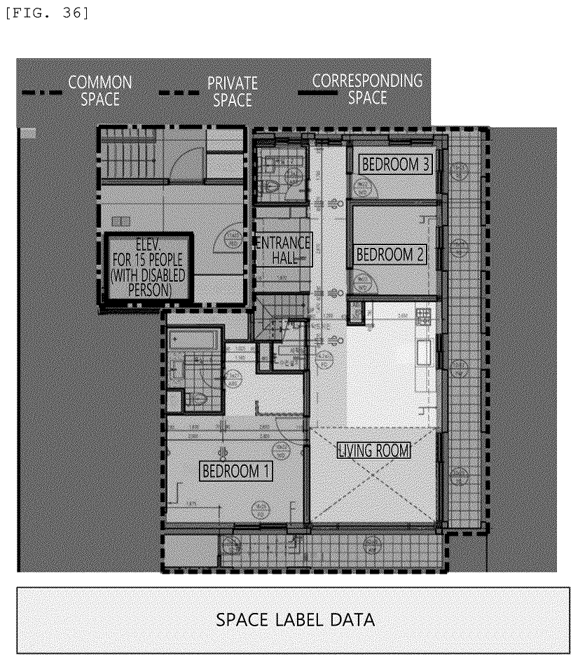

Referring to FIG. 36, a highlighted part indicates the elevator.

The elevator is a common space and includes a symbol indicating the elevator and a block.

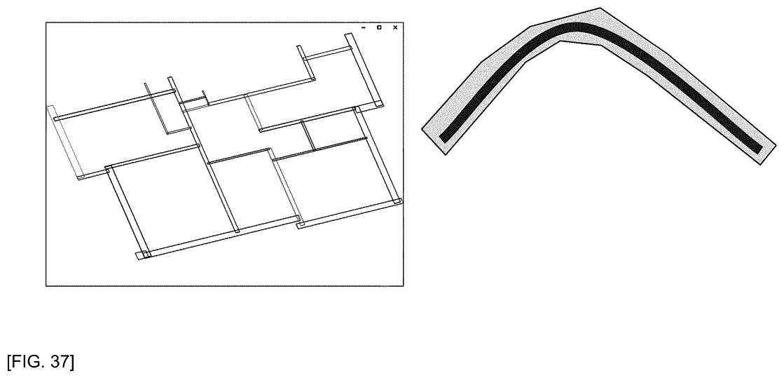

FIGS. 37 to 39 are views for explaining common rules.

The space is configured by a plurality of polygons and a straight wall needs to be represented as rectangularly as possible. The longest straight needs to be included to represent the space and a start point and an end point need to meet. A curved section is represented by a polygon, rather than a quadrangle and a space class and wall and interior material class do not overlap. The remaining part which does not correspond to the structure, the object, and the space class is labeled as a background and each class needs to be created as one file.

The application also provides a computer storage medium. In the computer storage medium, a program instruction is stored and when the program instruction is executed by a processor, the above-described method for automatically designing air conditioning equipment piping based on an artificial intelligence model is implemented. The computer storage medium according to the exemplary embodiment of the present disclosure may be a U disk, a SD card, a PD optical drive, a mobile hard disk, a high-capacity floppy drive, a flash memory, a multimedia memory card, or a server, but is not necessarily limited thereto.

Even though it has been described above that all components of the exemplary embodiment of the present disclosure are combined as one component or operate to be combined, the present disclosure is not limited to the exemplary embodiment. In other words, one or more components may be selectively combined to be operated within a scope of the present disclosure. Further, all components may be implemented as one independent hardware but a part or all of the components are selectively combined to be implemented as a computer program which includes a program module which performs a part or all functions combined in one or plural hardwares. Further, such a computer program may be stored in a computer readable media such as a USB memory, a CD disk, or a flash memory to be read and executed by a computer to implement the exemplary embodiment of the present disclosure. The recording media of the computer program may include a magnetic recording medium or an optical recording medium.

The above description illustrates a technical spirit of the present disclosure as an example and various changes, modifications, and substitutions become apparent to those skilled in the art within a scope of an essential characteristic of the present disclosure. Therefore, as is evident from the foregoing description, the exemplary embodiments and accompanying drawings disclosed in the present disclosure do not limit the technical spirit of the present disclosure and the scope of the technical spirit is not limited by the exemplary embodiments and accompanying drawings. The protection scope of the present disclosure should be interpreted based on the following appended claims and it should be appreciated that all technical spirits included within a range equivalent thereto are included in the scope of the present disclosure.

What is claimed is:

1. An air conditioning equipment piping automatic design device based on an artificial intelligence model, comprising:
a memory which stores one or more programs to automatically design an air conditioning equipment piping based on an artificial intelligence model; and
one or more processors which perform operations according to one or more programs,
wherein the processor is configured to input an architecture drawing on which the air conditioning equipment is not displayed to the artificial intelligence model, generate air conditioning equipment installation information including an installation location of the air conditioning equipment or a piping route from the architecture drawing on which the air conditioning equipment is not displayed using the artificial intelligence model, and automatically generate an air conditioning equipment installation design drawing including the air conditioning equipment installation information.

2. The air conditioning equipment piping automatic design device based on an artificial intelligence model, according to claim 1, wherein the processor is configured to classify a purpose of a space from the architecture drawing on which the air conditioning equipment is not displayed, calculate an area of each classified space, calculate a cooling/heating load for each space, calculate a capacity of the air conditioning equipment based on the calculated cooling/heating load, and generate the air conditioning equipment installation information including a capacity, using the artificial intelligence model.

3. The air conditioning equipment piping automatic design device based on an artificial intelligence model, according to claim 2, wherein the processor is configured to classify a purpose of the space from the architecture drawing on which the air conditioning equipment is not displayed to identify a location of a utility room and generate the air conditioning equipment installation information to place the outdoor unit in the identified location of the utility room, using the artificial intelligence model.

4. The air conditioning equipment piping automatic design device based on an artificial intelligence model, according to claim 1, wherein the piping of the air conditioning equipment includes a refrigerant pipe, a drain pipe, and a branch pipe, a piping route of the drain pipe is determined according to information provided from the outside, and the processor generates the air conditioning equipment installation information including the piping route of the refrigerant pipe or the branch pipe, using the artificial intelligence model.

5. The air conditioning equipment piping automatic design device based on an artificial intelligence model, according to claim 1, wherein the processor is configured to classify the interior wall and the exterior wall from the architecture drawing on which the air conditioning equipment is not displayed, determine the piping route of the air conditioning equipment so as to detour the exterior wall and pass through or detour the interior wall, along the classified interior wall and exterior wall, and generate air conditioning equipment installation information to which the piping route is reflected, using the artificial intelligence model

6. The air conditioning equipment piping automatic design device based on an artificial intelligence model, according to claim 1, wherein the air conditioning equipment includes an indoor unit and an outdoor unit of an air conditioner, the piping of the air conditioning equipment includes a refrigerant pipe, a drain pipe, and a branch pipe, and
the processor is configured to individually generate air conditioning equipment installation information for each of the indoor unit, the outdoor unit, the refrigerant pipe, the drain pipe, and the branch pipe, using the artificial intelligence model, and individually generate the air conditioning equipment installation design drawing which reflects air conditioning equipment installation information for each of the indoor unit, the outdoor unit, the refrigerant pipe, the drain pipe, and the branch pipe which is individually generated.

7. The air conditioning equipment piping automatic design device based on an artificial intelligence model, according to claim 1, wherein the artificial intelligence model is a vision transformer (ViT) based model.

8. An air conditioning equipment piping automatic design method performed by a device including a memory which stores one or more programs to automatically design an air conditioning equipment piping based on an artificial intelligence model; and one or more processors which perform operations according to one or more programs, the method comprising:
inputting an architecture drawing on which an air conditioning equipment is not displayed to the artificial intelligence model;
generating air conditioning equipment installation information including an installation location of the air conditioning equipment or a piping route from the architecture drawing on which the air conditioning equipment is not displayed using the artificial intelligence model; and
automatically generating an air conditioning equipment installation design drawing including the air conditioning equipment installation information.

9. The air conditioning equipment piping automatic design method based on an artificial intelligence model, according to claim 8, wherein in the generating of air conditioning equipment installation information, the artificial intelligence model is used to classify a purpose of a space from an architecture drawing on which the air conditioning equipment is not displayed, calculate an area of each classified space, calculate a cooling/heating load for each space, calculate a capacity of the air conditioning equipment based on the calculated cooling/heating load, and generate the air conditioning equipment installation information including a capacity.

10. The air conditioning equipment piping automatic design method based on an artificial intelligence model, according to claim 9, wherein in the generating of air conditioning equipment installation information, the artificial intelligence model is used to classify a purpose of the space from the architecture drawing on which the air conditioning equipment is not displayed to identify a location of a utility room and generate the air conditioning equipment installation information to place the outdoor unit in the identified location of the utility room.

11. The air conditioning equipment piping automatic design method based on an artificial intelligence model, according to claim 8, wherein the piping of the air conditioning equipment includes a refrigerant pipe, a drain pipe, and a branch pipe, and a piping route of the drain pipe is determined according to information provided from the outside, and
in the generating of air conditioning equipment installation information, the artificial intelligence model is used to generate air conditioning equipment installation information including a piping route of the refrigerant pipe or the branch pipe.

12. The air conditioning equipment piping automatic design method based on an artificial intelligence model, according to claim 8, wherein in the generating of air conditioning equipment installation information, the artificial intelligence model is used to classify the interior wall and the exterior wall from the architecture drawing on which the air conditioning equipment is not displayed, determine the piping route of the air conditioning equipment so as to detour the exterior wall and pass through or detour the interior wall, along the classified interior wall and exterior wall, and generate air conditioning equipment installation information to which the piping route is reflected.

13. The air conditioning equipment piping automatic design method based on an artificial intelligence model, according to claim 8, wherein the air conditioning equipment includes an indoor unit and an outdoor unit of an air conditioner, the piping of the air conditioning equipment includes a refrigerant pipe, a drain pipe, and a branch pipe,
in the generating of air conditioning equipment installation information, the artificial intelligence model is used to individually generate air conditioning equipment installation information for each of the indoor unit, the outdoor unit, the refrigerant pipe, the drain pipe, and the branch pipe, and
in the automatically generating of air conditioning equipment installation design drawing, the air conditioning equipment installation design drawings which reflects air conditioning equipment installation information for each of the indoor unit, the outdoor unit, the refrigerant pipe, the drain pipe, and the branch pipe which is individually generated are individually generated.

14. A computer program stored in a computer readable recording medium to allow a computer to execute the air conditioning equipment piping automatic design method based on an artificial intelligence model according to claim 8.
